(19) United States
(12) Patent Application Publication
(10) Pub. No.: US 2007/0109844 A1
(43) Pub. Date: May 17, 2007

(54) Semiconductor memory device and method for driving semiconductor memory device

(75) Inventors: Tomoki Higashi, Yokohama-Shi (JP); Takashi Ohsawa, Yokohama-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/476,878

(22) Filed: Jun. 29, 2006

(30) Foreign Application Priority Data
Nov. 14, 2005 (JP) 2005-328593

(51) Int. Cl. G11C 11/34

(52) U.S. Cl. 365/184; 365/150

(57) ABSTRACT

A semiconductor memory device includes a memory cell including a floating body region in an electrically floating state and storing data by accumulating or discharging charges in or from the floating body region; a memory cell array including a plurality of the memory cells; a word line connected to a gate of the memory cell; a bit line connected to a diffusion layer of the memory cell; a sense amplifier connected to the bit line; and a decoder applying a first potential to the word line when data “1” is written to the memory cell and applying a second potential different from the first potential to the word line when data “0” is written to the memory cell.

### CROSS-REFERENCE TO RELATED APPLICATION

This application is based upon and claims the benefit of priority from the prior Japanese Patent Applications No. 2005-328593, filed on Nov. 14, 2005, the entire contents of which are incorporated herein by reference.

### BACKGROUND OF THE INVENTION

1. Field of the Invention

The present invention relates to a semiconductor memory device and a method for driving a semiconductor memory.

2. Related Art

In recent years, there has been known FBC (floating body cell) memory device as a semiconductor memory device that is expected to replace DRAM. The FBC memory device is configured such that MOS transistors each including a floating body (hereinafter, also “body region”) are formed on a SOI (silicon on insulator) substrate. Each FBC stores data “1” or “0” depending on the number of majority carrier accumulated in this body region.

In a conventional FBC memory device, a potential of a word line when the data “0” is written to a memory cell is equal to that of the word line when the data “1” is written to the memory cell. For instance, the data “1” is written to the memory cell under conditions that the potential of the word line is 1.5 volt, a potential of a bit line is 2.2 volts, and a potential of a source line is 0 volt. The data “0” is written to the memory cell under conditions that the potential of the word line is 1.5 volts, the potential of the bit line is −1.5 volts, and the potential of the source line is 0 volt. In this case, when the data “0” is written to the memory cell, a relatively high potential of 3 volts is applied between a gate and a drain of the memory cell.

If a high voltage is applied between the gate and the drain of the memory cell when the data “0” is written to the memory cell, the current applied to the memory cell to which the data “0” is written increases. As a result, power consumption of the semiconductor memory device is disadvantageously increased.

### SUMMARY OF THE INVENTION

A semiconductor memory device according to an embodiment of the present invention comprises a memory cell including a floating body region in an electrically floating state and storing data by accumulating or discharging charges in or from the floating body region; a memory cell array including a plurality of the memory cells; a word line connected to a gate of the memory cell; a bit line connected to a diffusion layer of the memory cell; a sense amplifier connected to the bit line; and a decoder applying a first potential to the word line when data “1” is written to the memory cell and applying a second potential different from the first potential to the word line when data “0” is written to the memory cell.

A method for driving a semiconductor memory device according to an embodiment of the present invention, the semiconductor memory device comprising a memory cell including a floating body region in an electrically floating state and storing data by accumulating or discharging charges in or from the floating body region; a memory cell array including a plurality of the memory cells; a word line connected to a gate of the memory cell; a bit line connected to a diffusion layer of the memory cell; a sense amplifier connected to the bit line; and a decoder applying potentials to the word line,

the method comprises applying a first potential to the word line when data “1” is written to the memory cell; and applying a second potential different from the first potential to the word line when data “0” is written to the memory cell.

### BRIEF DESCRIPTION OF THE DRAWINGS

FIG. 1 is a block diagram of a configuration of a semiconductor memory device 100 according to a first embodiment;

FIG. 2 is a circuit diagram of a configuration of the sense amplifier S/A;

FIG. 3 is a circuit diagram of a configuration of the row decoder RD according to the first embodiment;

FIG. 4 is a circuit diagram of a configuration of the S/A driver SAD according to the first embodiment;

FIG. 5 is a table of potentials applied to the memory cell MC at the data writing, the data retention, and the data reading, respectively;

FIG. 6 is a timing chart of a data read operation performed by the semiconductor memory device 100 according to the first embodiment;

FIG. 7 is a timing chart of a data write operation performed by the semiconductor memory device 100 according to the first embodiment;

FIG. 8 is a timing chart of the delayed write operation performed by the semiconductor memory device 100 according to the first embodiment;

FIG. 9 is a timing chart of the other delayed write operation performed by the semiconductor memory device 100 according to the first embodiment;

FIG. 10 is a timing chart of a refresh operation performed by the semiconductor memory device 100 according to the first embodiment;

FIG. 11 is a circuit diagram of a configuration of the row decoder RD according to the second embodiment;

FIG. 12 is a table of potentials applied to the memory cell MC at the data writing, data retention, and data reading, respectively;

FIG. 13 is a timing chart of a data read operation performed by a semiconductor memory device 200 according to the second embodiment;

FIG. 14 is a circuit diagram of a configuration of a row decoder RD according to the third embodiment;

FIG. 15 is a circuit diagram of a configuration of a S/A driver SAD according to the third embodiment;

FIG. 16 is a timing chart of the refresh operation performed by the semiconductor memory device according to the third embodiment;

FIG. 17 is a circuit diagram of a configuration of the row decoder RD according to the fourth embodiment;

FIG. 18 is a timing chart of the refresh operation performed by the semiconductor memory according to the fourth embodiment;

FIG. 19 is a circuit diagram of a row decoder RD of a semiconductor memory device according to a fifth embodiment; and

FIG. 20 is a circuit diagram of a configuration of a row decoder RD of a semiconductor memory device according to a sixth embodiment.

### DETAILED DESCRIPTION OF THE INVENTION

Ordinary operations performed by an FBC memory will be briefly explained. The FBC memory is a semiconductor memory in which each SOI transistor stores binary data of “1” or “0” depending on the number of holes accumulated in the floating body of the SOI transistor. If the data “0” is written to an FBC memory cell, then the potential of a bit line BL is set low and a PN junction between a body and a drain of the FBC memory cell is biased in a forward direction. By doing so, the holes accumulated in the body region are discharged and the potential of the body region is reduced (deepened). Therefore, a threshold of a memory cell MC that stores the data “0” is relatively high.

To write the data “1” to the FBC memory cell, a word line WL and a bit line BL are set to have high potentials, respectively, and the memory cell MC is biased into a pentode (saturated) state. This cause impact ionization and accumulates holes in the body. The threshold of the memory cell MC that stores the data “1” is, therefore, made relatively low by body effect.

To read the data from the memory cell MC, the potential of the bit line BL is made low so as no to destroy the data, and the memory cell MC is caused to operate in a triode state. If so, it is possible to discriminate whether the data is “0” or “1” by detecting a difference in a drain current generated by a difference in the number of holes accumulated in the body.

In a data holding state, the potential of the word line WL connected to the gate of the memory cell MC is set lower than those of the source and the drain thereof. By so setting, the memory cell MC in the data holding state is not disturbed while the other memory cells MC are accessed.

Hereafter, embodiments of the present invention will be explained with reference to the drawings. Note that the invention is not limited by the embodiments.

### First Embodiment

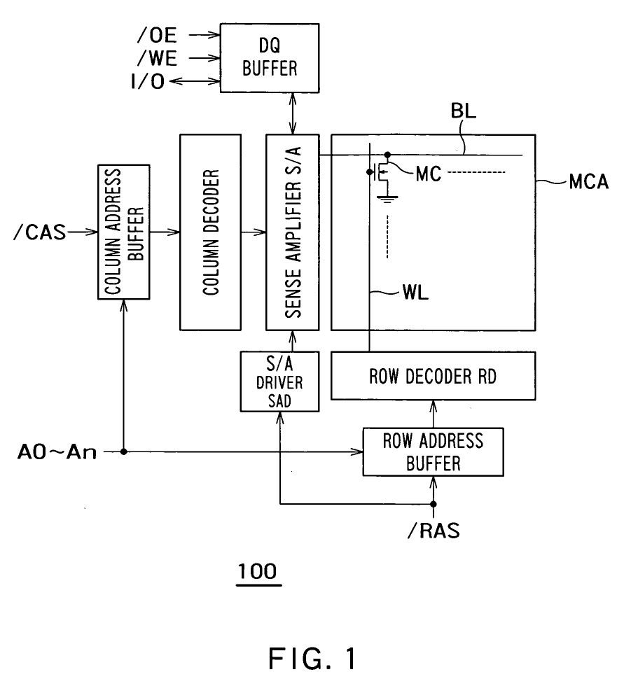

FIG. 1 is a block diagram of a configuration of a semiconductor memory device 100 according to a first embodiment of the present invention. The semiconductor memory device 100 includes memory cell arrays MCA, bit lines BL, a word line WL, a sense amplifier S/A, a column decoder, a column address buffer, a S/A driver SAD, a DQ buffer, a row decoder RD, and a row address buffer. In FIG. 1, the symbol bar “/” denotes an inverted signal (a bar).

The memory cell array MCA includes a plurality of memory cells MC arranged in a matrix. Each memory cell MC is a so-called FBC memory that includes a floating body region (not shown), and that stores data by accumulating or discharging charges in or from the floating body region.

Each word line WL is connected to gates of the memory cells MC arranged in a row direction. Each bit line BL is connected to drains or sources of the memory cells MC arranged in a column direction.

The sense amplifier S/A detects data stored in the memory cell MC selected by the word line WL and the bit line BL. In FIG. 1, the memory cell array MCA only one side of the sense amplifier S/A is shown. Actually, however, two memory cell arrays MCA are provided on both sides of the sense amplifier S/A, respectively. The sense amplifier S/A is connected to the respective bit lines BL of these memory cell arrays MCA. For example, the sense amplifier S/A receives a reference signal from a dummy cell connected to a bit line (BLR) connected to a right side of the sense amplifier S/A, and receives data from a bit line (BLL) connected to a left side thereof. By comparing this data with the reference signal, the sense amplifier S/A detects whether this data is “0” or “1”.

The column decoder selects one of the bit lines BL according to a column address signal. The column address buffer temporarily stores this column address signal. The S/A driver SAD controls the sense amplifier S/A. The DQ buffer holds input write data and read data to be output. The row decoder RD selects one of the word lines WL according to a row address signal.

As the memory cell array MCA, the sense amplifier S/A, the column decoder, the column address buffer, the DQ buffer, and the row address buffer, existing ones may be employed, respectively.

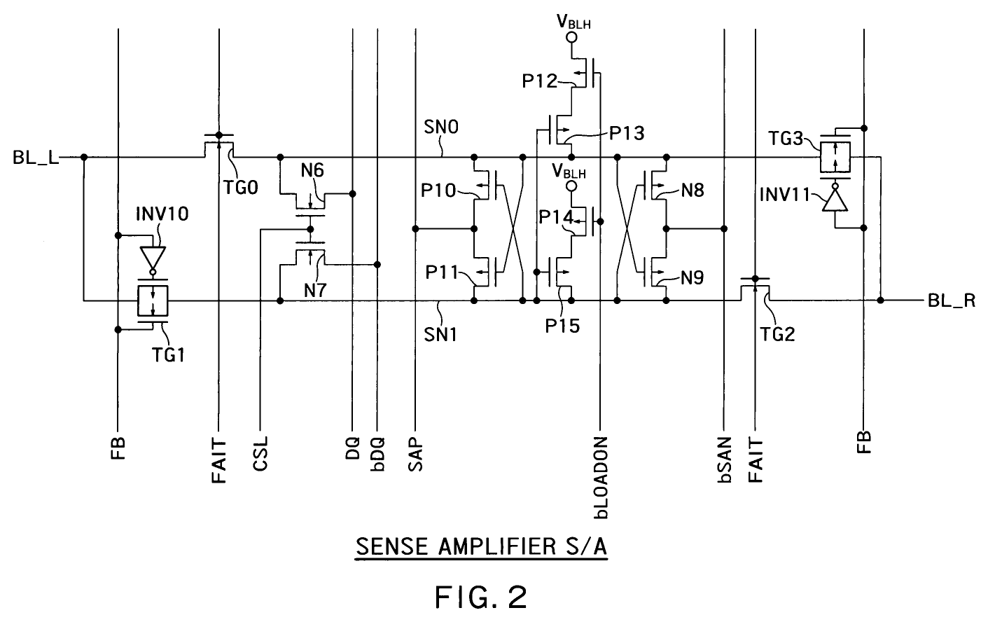

FIG. 2 is a circuit diagram of a configuration of the sense amplifier S/A. It is assumed herein that the bit line connected to a right side of the sense amplifier S/A is denoted by BLR and that the bit line connected to a left side thereof is denoted by BLL.

The sense amplifier S/A includes PMOS transistors P12 and P13 connected in series between a power supply VBLH and a sense node SN0, and PMOS transistors P14 and P15 connected in series between the power supply VBLH and a sense node SN1. A signal line bLOADON is connected to gates of the transistors P12 and P14. A gate of the transistor P13 is connected to the sense node SN0 and a gate of the transistor P15 is connected to the sense node SN1. The transistors P12 to P15 connect the power supply VBLH to the sense node SN0 or SN1 on the basis of a load enable signal bLOADON. A current can be thereby applied to the memory cell MC through the bit line BLL or BLR. The load enable signal bLOADON is a signal driven when the current is applied to the memory cell MC during data read.

The sense amplifier S/A has a dynamic clutch configuration. Namely, the sense amplifier S/A includes a latch circuit constituted by NMOS transistors N8 and N9 and a latch circuit constituted by PMOS transistors P10 and P11. The transistors N8 and N9 are connected in series between the sense nodes SN0 and SN1, and the transistors P10 and P11 are also connected in series therebetween. Gates of the transistors N8 and N9 are cross-coupled. That is, the gate of the transistor N8 is connected to the sense node SN1 and that of the transistor N9 is connected to the sense node SN0. Likewise, gates of the transistors P10 and P11 are cross-connected with each other. That is, the gate of the transistor N10 is connected to the sense node SN1 and that of the transistor N11 is connected to the sense node SN0.

A power supply signal bSAN used to latch data is connected between the transistors N8 and N9. A power supply signal SAP used to latch data is connected between the transistors P10 and P11.

The sense amplifier S/A also includes transfer gates TG0 to TG3. The transfer gate TG0 is controlled by a signal FAIT driven when data is read from the memory cell MC, whereby the bit line BLL can be connected to the sense node SN0. The transfer gate TG2 is controlled by the signal FAIT, whereby the bit line BLR can be connected to the sense node SN1. The transfer gate TG1 is controlled by a feedback signal FB driven when data is written to or written back to the memory cell MC, whereby the bit line BLL can be connected to the sense node SN1. The transfer gate TG3 is controlled by the signal FB driven when data is written to or written back to the memory cell MC, whereby the bit line BLR can be connected to the sense node SN0.

The sense amplifier S/A further includes PMOS transfer gates P10 and P11 connected in series between the sense nodes SN0 and SN1. The transfer gates P10 and P11 are connected to a column select line CSL connected to buffer signals DQ and bDQ.

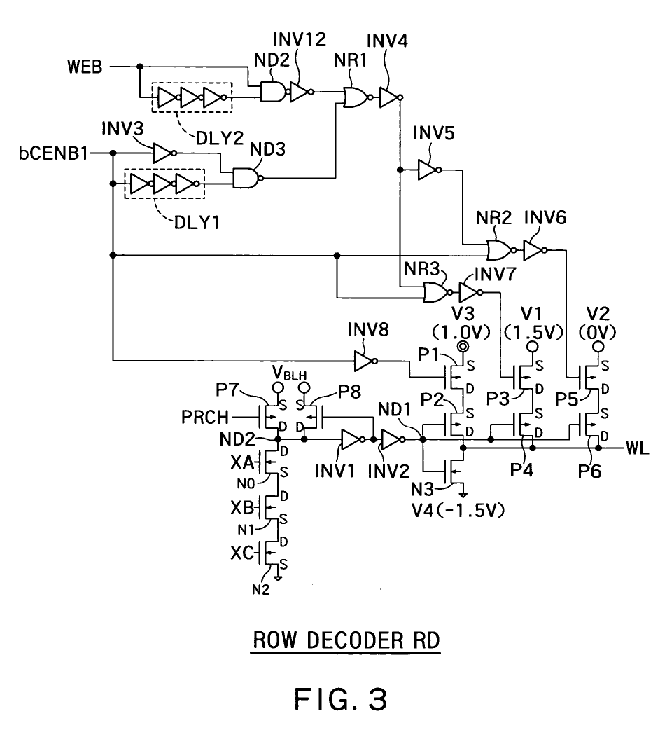

FIG. 3 is a circuit diagram of a configuration of the row decoder RD according to the first embodiment of the present invention. The row decoder RD is configured so that one of a first power supply V1, a second power supply V2, a third power supply V3, and a fourth power supply V4 is connected to the word line WL based on a precharge signal PRCH, a column enable signal bCENB1, and a write enable signal WEB.

For example, the first to the fourth power supplies V1 to V4 can supply 1.5 volts as a first potential, 0 volt as a second potential, 1.0 volt as a third potential, and −1.5 volts as a fourth potential, respectively. The first power supply V1 is connected to the word line WL when the data “1” is written to the memory cell MC. The second power supply V2 is connected to the word line WL when the data “0” is written to the memory cell MC. The third power supply V3 is connected to the word line WL when the data is read from the memory cell MC. The fourth power supply V4 is connected to the word line WL when the data stored in the memory cell MC is held. The potentials of the first to the fourth power supplies V1 to V4 have a relationship of V4<V2<V3<V1.

Furthermore, the potential of the second power supply V2 is higher than the threshold of the memory cell MC. This makes it possible for the data “0” to be written to the memory cell MC using the second power supply V2.

FIG. 3 shows only parts corresponding to one word line WL. Actually, however, the row decoder RD is connected similarly to all word lines WL. One of the word lines WL is selected based on row address signals XA to XC.

PMOS transistors P1 and P2 are connected in series between the third power supply V3 and the word line WL. A NMOS transistor N3 is connected between the fourth power supply V4 and the word line WL.

A gate of the PMOS transistor P1 is connected to the column enable signal bCENB1 through an inverter INV8. Gates of the PMOS transistor P2 and a NMOS transistor N3 are connected in common to a first node ND1.

PMOS transistors P3 and P4 are connected in series between the first power supply V1 and the word line WL. A gate of the PMOS transistor P3 is connected to an output of a NOR gate NR3 through an inverter INV7. A gate of the PMOS transistor P4 is connected to the first node ND1.

PMOS transistors P5 and P6 are connected in series between the second power supply V2 and the word line WL. A gate of the PMOS transistor P5 is connected to an output of a NOR gate NR2 through an inverter INV6. A gate of the PMOS transistor P6 is connected to the first node ND1.

A PMOS transistor P7 and NMOS transistors N0 to N2 are connected in series between the power supply VBLH and the fourth power supply V4.

A second node ND2 between the PMOS transistor P7 and the NMOS transistor N0 is connected to the first node ND1 through inverters INV1 and INV2. A gate of the PMOS transistor P7 receives the precharge signal PRCH. Gates of the NMOS transistors N0 to N2 receive pre-decoded signals XA, XB, and XC, respectively. The signals XA, XB, and XC are address signals received from the row address buffer.

A PMOS transistor P8 is connected between the power supply VBLH and the second node ND2. A gate of the PMOS transistor P8 is connected between the inverters INV1 and INV2.

The write enable signal WEB is input to one input of a two-input NAND gate ND2. An inverted signal of the signal WEB is input to the other input of the NAND gate ND2 through a delay circuit DLY2. The signal WEB is, therefore, input to the two inputs of the NAND gate ND2 at different timings, respectively. An end of a period for writing the data “0” to the memory cell MC is thereby determined.

The column enable signal bCENB1 is input to one input of a two-input NAND gate ND3 through an inverter INV3. An inverted signal of the signal bCENB1 is input to the other input of the NAND gate ND3 through a delay circuit DLY1. The column enable signal bCENB1 is the signal that indicates that the signal read from the memory cell MC is latched by the sense amplifier S/A.

An output of the NAND gate ND2 is input to one input of a NOR gate NR1 through an inverter INV12, and an output of the NAND gate ND3 is input to the other input thereof.

An output of the NOR gate NR1 is input to one input of a two-input NOR gate NR2 through inverters INV4 and INV5, and the signal bCENB1 is input to the other input thereof. An output of the NOR gate NR2 is connected to the gate of the PMOS transistor P5 through the inverter INV6.

The output of the NOR gate NR1 is input to one input of a two-input NOR gate NR3 through the inverter INV4, and the signal bCENB1 is input to the other input thereof. An output of the NOR gate NR3 is connected to the gate of the PMOS transistor P3 through the inverter INV7.

The signal bCENB1 is applied to the gate of the PMOS transistor P1 through the inverter INV8.

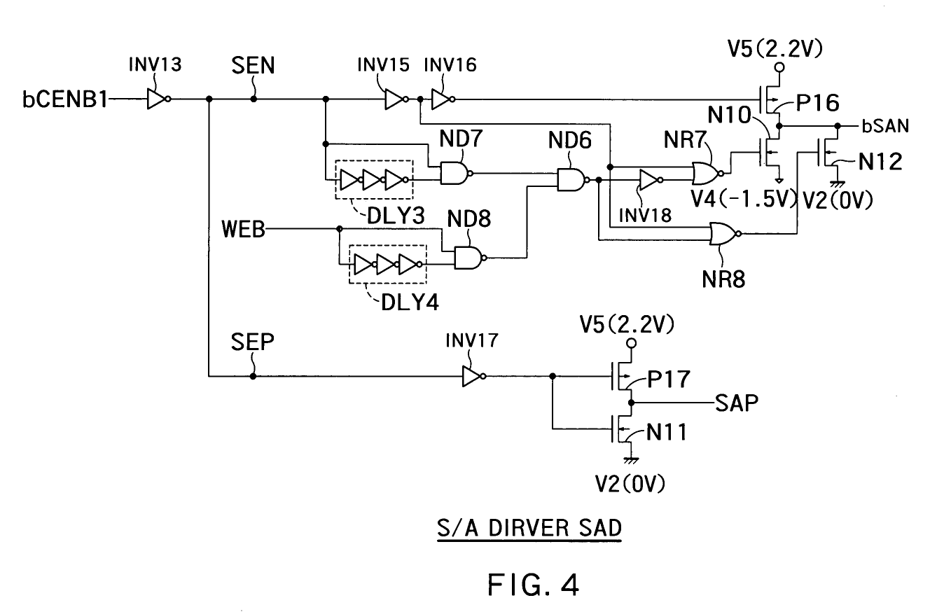

FIG. 4 is a circuit diagram of a configuration of the S/A driver SAD according to the first embodiment of the present invention. A PMOS transistor P16 and a NMOS transistor N10 are connected in series between a fifth power supply V5 and the fourth power supply V4 (−1.5 volts). The fifth power supply V5 can supply, for example, 2.2 volts as a fifth potential. This fifth potential is a potential applied to the bit line BL when the data “1” is written to the memory cell MC. The signal bSAN is output from between the PMOS transistor P16 and the NMOS transistor N10. A NMOS transistor N12 is connected between a signal bSAN line and the second power supply V2.

A PMOS transistor P17 and a NMOS transistor N11 are connected in series between the fifth power supply V5 and the second power supply V2 (0 volt).

In the S/A driver SAD, the fourth power supply V4 is connected to the bit line BL as the signal bSAN when the data “0” is written to the memory cell MC. The fifth power supply V5 is connected to the bit line BL as the signal bSAN when the data “1” is written to the memory cell MC. The second power supply V2 is connected to the bit line BL as the signal bSAN when the data stored in the memory cell MC is retained. The potentials of the second power supply V2, the fourth power supply V4, and the fifth power supply V5 have a relationship of V4<V2<V5.

The signal bCENB1 is converted into signals SEN and SEP through an inverter INV13.

The signal SEN is connected to a gate of the PMOS transistor P16 through inverters INV15 and INV16. The signal SEP is connected to gates of the PMOS transistor P17 and the NMOS transistor N11 through an inverter INV17.

The signal SEN is input to one input of a two-input NAND gate ND7 and the inverted signal of the signal SEN is input to the other input thereof through a delay circuit DLY3. The write enable signal WEB is input to one input of a two-input NAND gate ND8 and the inverted signal of the signal WEB is input to the other input thereof through a delay circuit DLY4. An output of the NAND gate ND7 is input to one input of a two-input NAND gate ND6 and an output of the NAND gate ND8 is input to the other input thereof.

The delay circuit DLY3 delays the inverted signal of the signal SEN by as much as a period for reading the data from the memory cell MC. The delay circuit DLY4 delays the inverted signal of the signal WEB by as much as a period for reading the data from the memory cell MC.

The signal SEN is input to one input of a two-input NOR gate NR7 through an inverter INV15, and an output of the NAND gate ND6 is input to the other input thereof through an inverter INV18. An output of the NOR gate NR7 is connected to the gate of the NMOS transistor N10. The signal SEN is input to one of inputs of a two-input NOR gate NR8 through the inverter INV15, and the output of the NAND gate ND6 is input to the other input thereof. An output of the NOR gate NR8 is connected to a gate of the NMOS transistor N12.

Each of the delay circuits DLY1 to DLY4 is constituted by three inverters connected in series. However, it suffices that each of the delay circuits DLY1 to DLY4 is constituted by odd-numbered inverters, as which resistors, capacitors, or the like may be used.

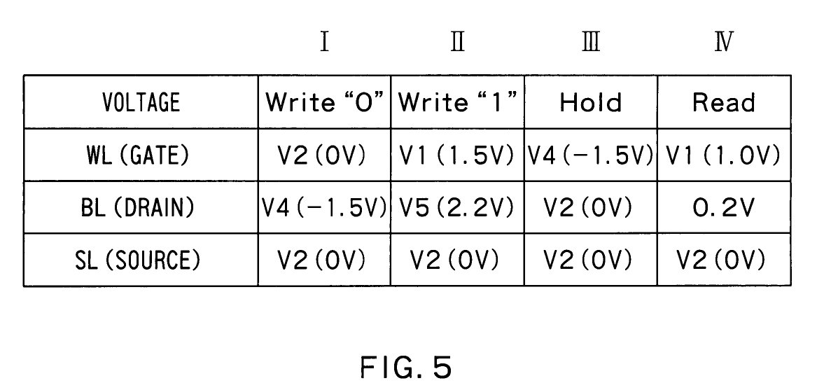

FIG. 5 is a table of potentials applied to the memory cell MC at the data writing, the data retention, and the data reading from the memory cell MC, respectively. In FIG. 5, states I, II, III, and IV are shown. In the state I, voltages shown therein are applied to the word line WL, the bit line BL, and the source line SL, respectively when the data “0” is written to the memory cell MC. In the state II, voltages shown therein are applied to the word line WL, the bit line BL, and the source line SL, respectively when the data “1” is written to the memory cell MC. In the state III, voltages shown therein are applied to the word line WL, the bit line BL, and the source line SL, respectively when the data is held in the memory cell MC. In the state IV, voltages shown therein are applied to the word line WL, the bit line BL, and the source line SL, respectively when the data is read from the memory cell MC.

[Read Operation]

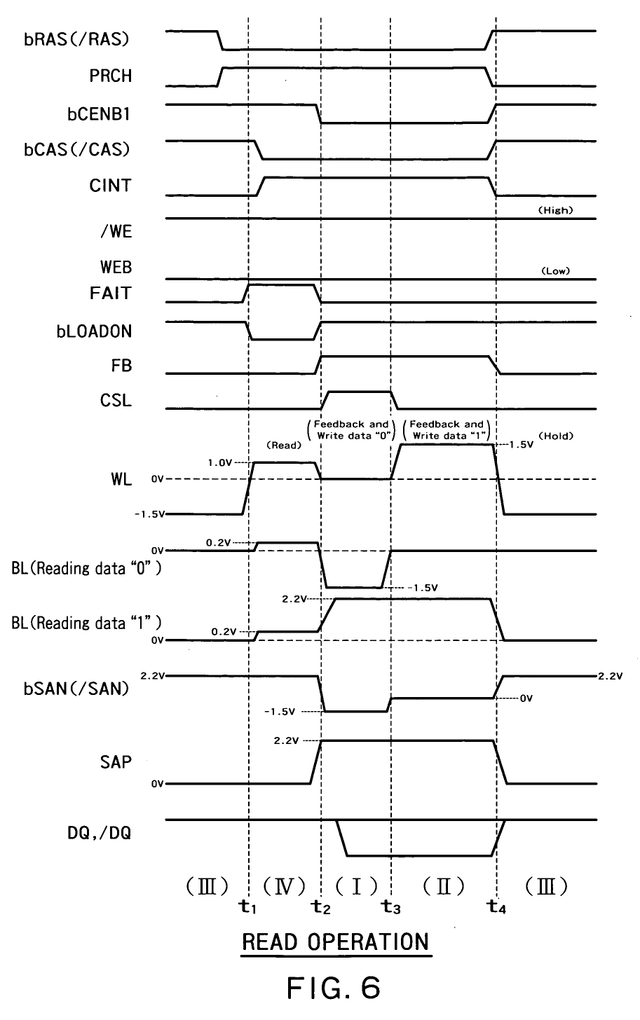

FIG. 6 is a timing chart of a data read operation performed by the semiconductor memory device 100 according to the first embodiment of the present invention. In the read operation, the data stored in the memory cell MC is read to the sense amplifier S/A (at a time t1 to a time t2), written back to the memory cell MC (at the time t2 to a time t4), and transmitted to the DQ buffer. The data is read from the DQ buffer.

As shown in FIG. 6, initially, the precharge signal PRCH is at low level (hereinafter, “LOW”), the signal bCENB1 is at high level (hereinafter, “HIGH”), and the signal WEB is LOW. The word line WL shown in FIG. 3 is thereby connected to the fourth power supply V4 and precharged to −1.5 volts. At this moment, the PMOS transistors P2, P4, and P6 are turned off. The semiconductor memory device 100 is in the data holding state III shown in FIG. 5.

When a signal bRAS is made LOW and the signal PRCH is made HIGH, the word line WL shown in FIG. 3 is disconnected from the fourth power supply V4. The precharging of the word line WL is thereby released.

When the word line WL shown in FIG. 3 is selected, all of the pre-decoded signals XA, XB, and XC are made HIGH. The second node ND2 is thereby made LOW, and the transistors P2, P4, and P6 are turned on. If one of the transistors P1, P3, and P5 is turned on, additionally, one of the third power supply V3, the first power supply V1, and the second power supply V2 can be connected to the word line WL. This state is the state in which the word line WL has been selected.

In the state III, since the signal bCENB1 is HIGH, the S/A driver shown in FIG. 4 outputs the fifth potential (2.2 volts) as the signal bSAN and the second potential (0 volt) as the signal SAP.

In the data read operation (from the time t1 to the time t4), the write enable signal WEB for writing the data is not activated but kept LOW. Therefore, the row decoder RD shown in FIG. 3 and the S/A driver SAD shown in FIG. 4 are controlled by the signal bCENB1 irrespective of the signal WEB.

At the time t1, since the signal bCENB1 is HIGH, the transistor P1 shown in FIG. 3 is turned on and the transistors P3 and P5 are turned off. Accordingly, in the row decoder RD shown in FIG. 3, the third power supply V3 (1.0 volt) is connected to the word line WL.

Because of the HIGH signal bCENB1, the S/A driver SAD shown in FIG. 4 outputs the fifth potential (2.2 volts) as the signal bSAN and the second potential (0 volt) as the signal SAP.

At the same time, the signal FAIT is made HIGH. Therefore, the bit line BLL is connected to the sense node SN0, and the bit line BLR is connected to the sense node SN1 as shown in FIG. 2.

When the signal bLOADON is next activated into LOW, the power supply VBLH shown in FIG. 2 is connected to the sense nodes SN0 and SN1. The current is thereby applied from the power supply VBLH to the memory cell MC. At this moment, the voltage applied to the drain of the memory cell MC through the bit lines BLL and BLR is, for example, 0.2 volt. If the memory cell MC is an n-FBC memory, a threshold of the memory cell MC that stores the data “0” is higher than a threshold of the memory cell MC that stores the data “1”. Therefore, the current applied to the memory cell MC that stores the data “0” is lower than that applied to the memory cell MC that stores the data “1”. Thus, if the sense node SN0 is connected to the memory cell MC that stores the data “0”, the potential of the sense node SN0 has relatively high. If the sense node SN0 is connected to the memory cell MC that stores the data “1”, the potential of the sense node SN0 is relatively low. As a result, a potential difference is generated between the bit line BLL for transmitting the data from the memory cell MC and the bit line BLR for transmitting the reference signal from the dummy cell.

At the moment this potential difference is generated, the signal FAIT is made LOW and the sense nodes SN0 and SN1 are disconnected from the bit lines BLL and BLR (at the time t2). In this case, if the sense node SN0 is connected to the memory cell MC that stores the data “0”, the potential of the sense node SN0 is relatively high. Therefore, the potential of the signal bSAN appears on the sense node SN1. On the other hand, if the sense node SN0 is connected to the memory cell MC that stores the data “1”, the potential of the sense node SN0 is relatively low. Therefore, the potential of the signal SAP appears on the sense node SN1. In this way, the data store in the memory cell MC is latched.

At the same time, the CMOS transfer gates TG1 and TG3 for writing the data are turned on in response to the feedback signal FB. As a result, if the sense node SN0 is connected to the memory cell MC that stores the data “0”, the potential of the bit line BLL is equal to that of the signal bSAN through the transfer gate TG1. If the sense node SN0 is connected to the memory cell MC that stores the data “1”, the potential of the bit line BLL is equal to that of the signal SAP through the transfer gate TG1 (at the times t2 to t3).

The column select line CSL is then made HIGH and the data is transferred to the DQ and bDQ lines shown in FIG. 2. The data can be thereby read from the DQ buffer.

(Operation of the Row Decoder RD from t2 to t4)

At the time t2, when the signal bCENB1 is activated into LOW, the second power supply V2 (0 volt) is connected to the word line WL in the row decoder RD shown in FIG. 2. By doing so, the data “0” among the data thus read is written back to the memory cell MC. A process of connecting the second power supply V2 (0 volt) to the word line WL will be explained in detail.

As shown in FIG. 3, the delay circuit DLY1 is provided on the other input of the NAND gate ND3. Therefore, the signal bCENB1 is input to the other input of the NAND gate ND3 at a delayed timing from the timing at which the signal is input to one input thereof.

Right after the signal bCENB1 turns LOW, the HIGH signal and the LOW signal are input to the NAND gate ND3. The NAND gate ND3, therefore, outputs a HIGH signal. As a result, the NOR gate NR2 inputs a LOW signal through the inverter INV5 whereas the NOR gate NR3 inputs the HIGH signal through the inverter INV4. Furthermore, the signal bCENB1 (LOW) is input to the NOR gates NR2 and NR3, and the inverter INV8 without delay. Thus, the transistor P5 is turned on and the transistors P1 and P3 are turned off. As a result, the second power supply V2 is connected to the word line WL and the data “0” starts to be written back to the memory cell MC (State I).

When predetermined time passes since the signal bCENB1 turns LOW, the output of the delay circuit DLY1 also turns HIGH. Since the HIGH signals are input to the both inputs of the NAND gate ND3, respectively, the NAND gate ND3 outputs a LOW signal. As a result, the NOR gate NR2 inputs a HIGH signal through the inverter INV5 whereas the NOR gate NR3 inputs the LOW signal through the inverter INV4. Furthermore, the signal bCENB1 (LOW) is continuously input to the NOR gates NR2 and NR3 and the inverter INV8. Thus, the transistor P3 is turned on and the transistors P1 and P5 are turned off. As a result, the second power supply V2 (0 volt) is disconnected from the word line WL and the first power supply V1 (1.5 volts) is connected to the word line WL. The data “0” finishes to be written back to the memory cell MC and the data “1” starts to be written back thereto ((State I)-(State II)).

As can be seen, a start (t2) of writing back the data “0” is determined by activation of the signal bCENB1, and an end (t3) of restoring the data “0” is determined by the delay time of the delay circuit DLY1. In other words, the delay time of the delay circuit DLY1 provides for the data “0” restoring time.

At the time t4, the signal bCENB1 is deactivated into HIGH and the signal PRCH is deactivated into LOW. The row decoder RD thereby turns into the state III and the fourth power supply V4 (−1.5 volts) is connected to the word line WL.

(Operation of the S/A Driver SAD from t2 to t4)

At the time t2, when the signal bCENB1 is activated into LOW, the delay circuit DLY3 delays the signal SEN by as much as predetermined time in the S/A driver SAD shown in FIG. 2. Delay time of the delay circuit DLY3 may be equal to that of the delay circuit DLY1.

Right after the signal bCENB1 turns LOW, the HIGH signals are input to the both inputs of the NAND gate ND7, respectively. Thus, the transistor N10 is turned on and the transistors N12 and P16 are turned off. As a result, the S/A driver SAD outputs the fourth power supply V4 (−1.5 volts) as the signal bSAN and the fifth power supply V5 (2.2 volts) as the signal SAP. Namely, if the sense node SN0 is connected to the memory cell MC that stores the data “0”, the potential of the bit line BLL is equal to that of the fourth power supply V4 (−1.5 volts). If the sense node SN0 is connected to the memory cell MC that stores the data “1”, the potential of the bit line BLL is equal to that of the fifth power supply V5 (2.2 volts). In this state I, the write-back of the data “0” to the memory cell MC is executed.

At the time t3 after passage of predetermined time since the signal bCENB1 turns LOW, the output of the delay circuit DLY3 turns LOW. Thus, the transistor N12 is turned on and the transistor N10 is turned off. In addition, the transistor P16 is kept to be turned off. As a result, the S/A driver SAD outputs the second power supply V2 (0 volt) as the signal bSAN and keeps outputting the signal SAP as the fifth power supply V5 (2.2 volts). Namely, if the sense node SN0 is connected to the memory cell MC that stores the data “0”, the potential of the bit line BLL is equal to the second potential (0 volt). If the sense node SN0 is connected to the memory cell MC that stores the data “1”, the potential of the bit line BLL is kept equal to the fifth potential (2.2 volts). In this state II, the write-back of the data “1” to the memory cell MC is executed.

As can be seen, an end (t3) of writing back the data “0” is determined by the delay circuit DLY3. In other words, the delay time of the delay circuit DLY3 provides for the data “0” restoring time.

At the time t4, when the signal bCENB1 is deactivated into HIGH, the S/A driver SAD outputs the fifth potential (2.2 volts) as the signal bSAN similarly to the state III or IV, and outputs the second potential (0 volt) as the signal SAP. This state is kept for the data holding period after the time t4.

At the time of writing back the data “1” to the memory cell MC, the bit line BLL for which the data “1” is written to the memory cell MC is connected to the signal SAP and the potential of the bit line BLL is set to the fifth potential (2.2 volts). The bit line BLL for which the data “1” is already written to the memory cell MC is connected to the signal bSAN, and the potential of the bit line BLL is set to the second potential (0 volt), i.e., set equal to that of the source of the memory cell MC. By so setting, the data “1” can be restored to the memory cell MC that originally stores the data “1” without writing the data “1” to the memory cell MC to which the data “0” is restored.

[Write Operation]

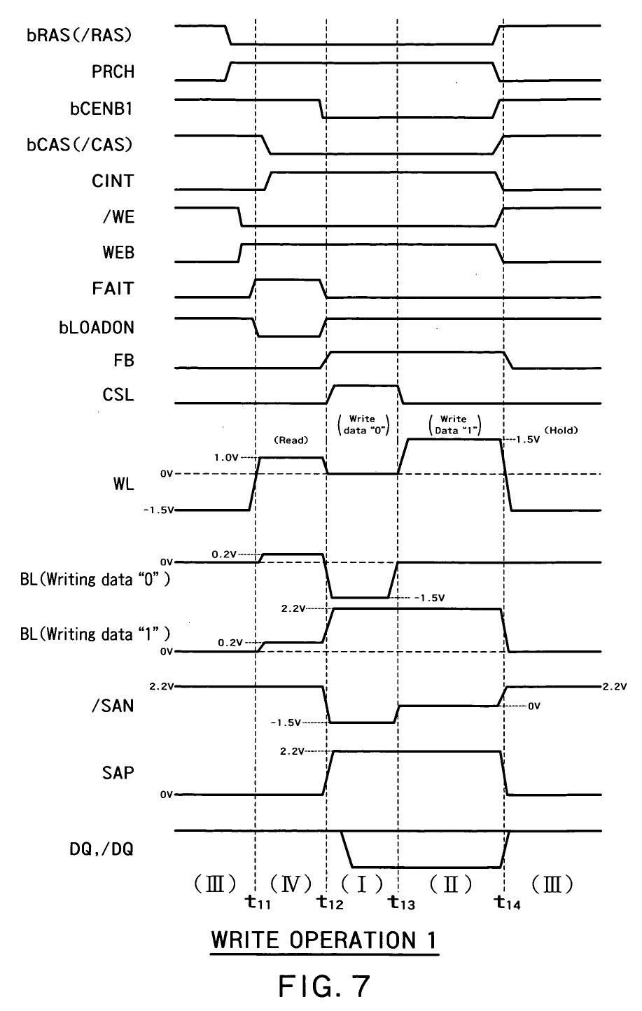

FIG. 7 is a timing chart of a data write operation performed by the semiconductor memory device 100 according to the first embodiment of the present invention. In the write operation, the data stored in the memory cell MC is read to the sense amplifier S/A (at t11 to t12). Thereafter, the data acquired from the DQ buffer is written to the memory cell MC the data of which is to be restored (at t2 to t4). In addition, the data read at the times t11 to t12 is written back to the memory cell MC the data of which is not changed. The memory cell MC to which data is to be written (rewritten) is selected by the write enable signal WEB. The data is thus written to each memory cell MC.

The chart shown in FIG. 7 differs from that shown in FIG. 6 in that the signal WEB is driven. The other signals than the signal WEB shown in FIG. 7 may be identical to those shown in FIG. 6.

Before the time t11, the signal WEB is activated into LOW. Therefore, the NAND gate ND2 shown in FIG. 3 and the NAND gate ND8 shown in FIG. 4 both keep HIGH signals, and the read operation is identical to the read operation (at t1 to t2) shown in FIG. 6.

During data write (t12 to t13), the column select signal CSL is activated into HIGH. The sense nodes SN0 and SN1 shown in FIG. 2 are thereby connected to the DQ line and the bDQ line, and the data from the DQ buffer is transmitted to the sense nodes SN0 and SN1. Namely, the data read from the memory cell MC and latched by the sense nodes SN0 and SN1 is updated to the data from the DQ buffer. At the same time, the data “0” is written to the memory cell MC.

At the time t13, the column select line CSL is made LOW, whereby the sense nodes SN0 and SN1 are disconnected from the DQ line and the bDQ line.

At the time t13 to a time t14, the data “1” is written to the memory cell MC. At this moment, the sense amplifier S/A either writes the data transmitted from the DQ buffer to the sense nodes SN0 and SN1 to the memory cell MC or writes back the data read from the memory cell MC at t11 to t12 to the memory cell MC.

The bit line BLL for which the data “0” is already written to the memory cell MC is connected to the signal bSAN and the potential thereof is set to the second potential (0 volt), i.e., set equal to the potential of the source of the memory cell MC. By so setting, the data “1” can be restored to the memory cell MC that originally stores the data “1” without writing the data “1” to the memory cell MC to which the data “0” is restored. Since detailed operations at this time are identical to those at the time t3 to the time t4 shown in FIG. 6, they will not be explained herein in detail.

In the operation shown in FIG. 7, the signal WEB is activated before data read (t12). Due to this, the write (rewrite) of the data from the DQ buffer can be executed simultaneously with the restore of the data read from the memory cell MC. The operation in which the signal WEB is activated before the data read (t12) will be referred to as “early write operation”.

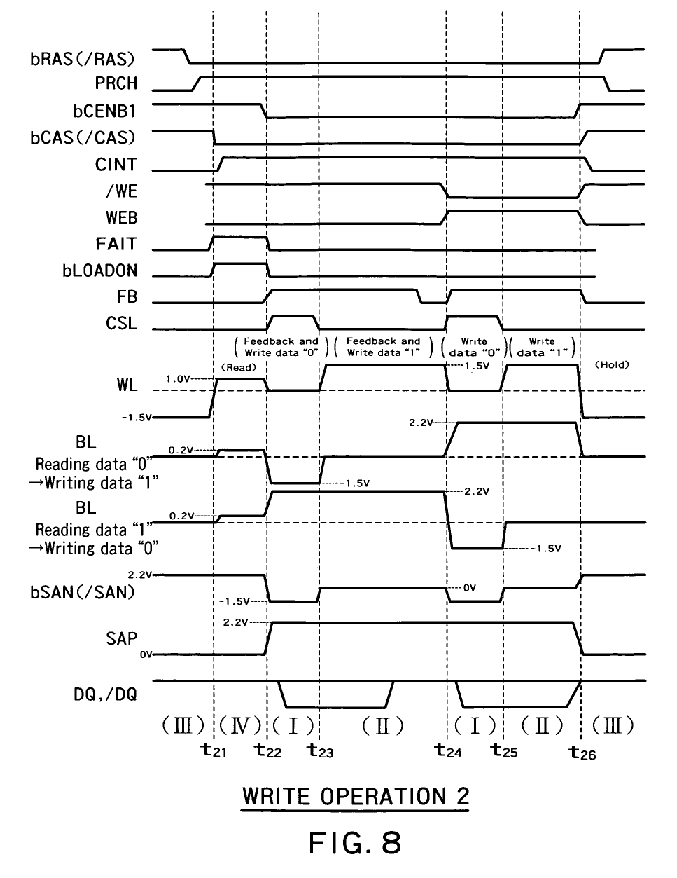

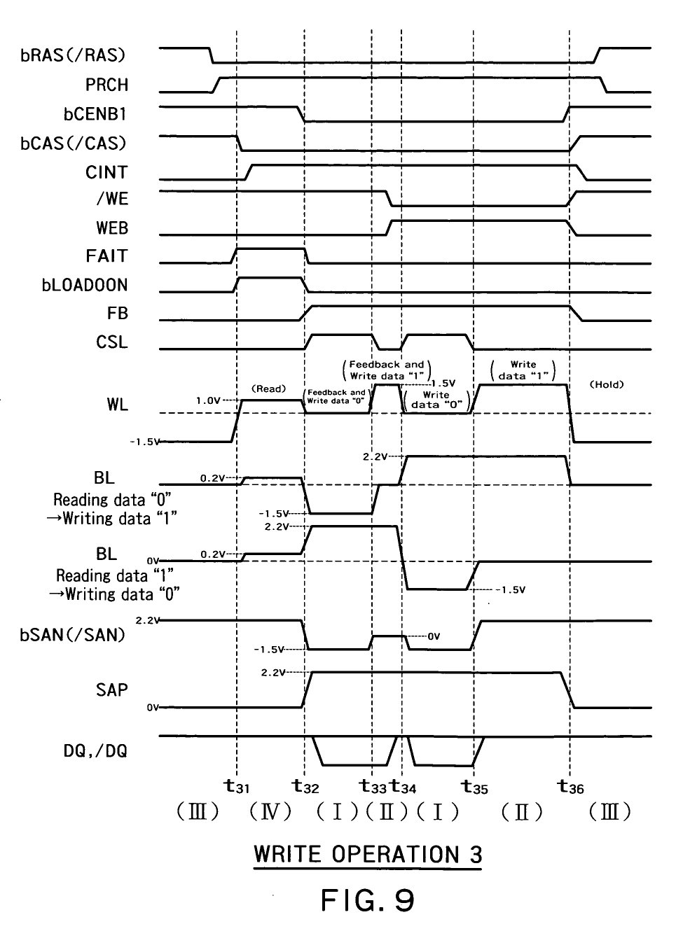

However, as shown in FIGS. 8 and 9, the signal WEB is sometimes activated after the data read operation (t12). A timing of activating the signal WEB may be set to an arbitrary time during which the signal bRAS is activated into LOW. This timing can be determined according to user's convenience. The operation in which the signal WEB is activated after the data read operation (t12) will be referred to as “delayed write operation”.

FIG. 8 is a timing chart of the delayed write operation performed by the semiconductor memory device 100 according to the first embodiment. Since operations up to t24 shown in FIG. 8 are identical to those up to t4 shown in FIG. 6, they will not be explained herein.

At t24, the signal WEB is activated into HIGH. The delay circuit DLY2 shown in FIG. 3 delays the signal WEB by as much as predetermined time before making the signal WEB from LOW to HIGH. Therefore, at the beginning of activating the signal WEB, HIGH signals are input to the both inputs of the NAND gate ND2, respectively, and the NAND gate ND2 outputs a LOW signal. In addition, the signal bCENB1 is LOW. As a result, at t24 to t25, the second power supply V2 (0 volt) is connected to the word line WL.

At t24 at which the signal WEB is activated into HIGH, the delay circuit DLY4 shown in FIG. 4 delays the signal WEB by as much as predetermined time before making the signal WEB from HIGH to LOW. Therefore, at the beginning of activating the signal WEB, HIGH signals are input to the both inputs of the NAND gate ND8, respectively, and the NAND gate ND8 outputs a LOW signal. The signal bCENB1 is LOW. Accordingly, the S/A driver SAD outputs the fourth potential (−1.5 volts) as the signal bSAN and the fifth potential (2.2 volts) as the signal SAP.

Furthermore, at t24, the column select line CSL is activated. Therefore, the data from the DQ buffer is transmitted to the sense nodes SN0 and SN1. To rewrite the data from “0” to “1” (in case of BL (“0” Read→“1” Write) shown in FIG. 8), the potential of the signal SAP is applied to the memory cell MC through the bit line BLL or BLR. To rewrite the data from “1” to “0” (in case of BL (“1” Read→“0” Write) shown in FIG. 8), the potential of the signal bSAN is applied to the memory cell MC through the bit line BLL or BLR. As a result, at t24 to t25, the state is the state I shown in FIG. 5. The data “0” is thereby written to the memory cell MC. At this time, since the potential of the word line WL is as low as 0 volt, the data “1” is not written to the memory cell MC.

After passage of the predetermined time since the signal WEB is activated, the delay circuit DLY2 shown in FIG. 3 makes the signal WEB LOW. Therefore, the NAND gate ND2 outputs a HIGH signal (at t25). The signal bCENB1 remains LOW. Accordingly, at t25 to t26, the first power supply V1 (1.5 volts) is connected to the word line WL.

After passage of the predetermined time since the signal WEB is activated, the delay circuit DLY4 shown in FIG. 4 makes the signal WEB LOW. Therefore, the NAND gate ND8 outputs a HIGH signal (at t25). The signal bCENB1 remains LOW. Accordingly, at t25 to t26, the S/A driver SAD outputs the second potential (0 volt) as the signal bSAN and the fifth potential (2.2 volts) as the signal SAP.

Furthermore, at t25, although the column select line CSL is LOW, the data “1” from the DQ buffer is latched by the sense nodes SN0 and SN1. Therefore, if the data is rewritten from “0” to “1”, the potential of the signal SAP is applied to the memory cell MC through the bit line BLL or BLR. If the data is restored from “1” to “0”, the potential of the signal bSAN is applied to the memory cell MC through the bit line BLL or BLR. As a result, at t24 to t25, the state is the state II shown in FIG. 5. The data “1” is thereby written to the memory cell MC. At this time, the potential of the signal bSAN is 0 volt and equal to the source potential of the memory cell MC. The data “1” is not, therefore, written to the memory cell MC to which the data “0” is already written.

At t26, the signals WEB and bCENB1 are deactivated and the signal PRCH is activated. The state, therefore, returns to the state III, thus turning into the data holding state.

FIG. 9 is a timing chart of the other delayed write operation performed by the semiconductor memory device 100 according to the first embodiment. Since operations up to t33 shown in FIG. 9 are identical to those up to t4 shown in FIG. 6, they will not be explained herein.

At times t33 to t34, the signal WEB is activated into HIGH. If the signal WEB is activated, then the write operation performed so far is interrupted, and the data latched by the sense nodes SN0 and SN1 are updated to the data from the DQ buffer. At the same time, the write operation restarts.

Since the data write operations from t34 to t36 are identical to those from t24 to t26 shown in FIG. 8, they will not be explained herein.

In each of the delayed write operations shown in FIGS. 8 and 9, the start of writing the data “0” (t24 or t34) is determined by activation of the write enable signal WEB. In addition, the end of writing the data “0” (t25 or t35) is determined by the delay time of the delay circuit DLY2 or DLY4. In other words, the delay time of the delay circuit DLY2 or DLY4 provides for the data “0” write time.

The delay circuit DLY 2 may be equal in delay time to the delay circuit DLY4. Furthermore, the delay circuits DLY1 to DLY4 may be equal to one another in delay time. This can facilitate designing the S/A driver SAD and the row decoder RD. Besides, since the data “0” write time can be set constant, the user can easily determine the data write timing.

[Refresh Operation]

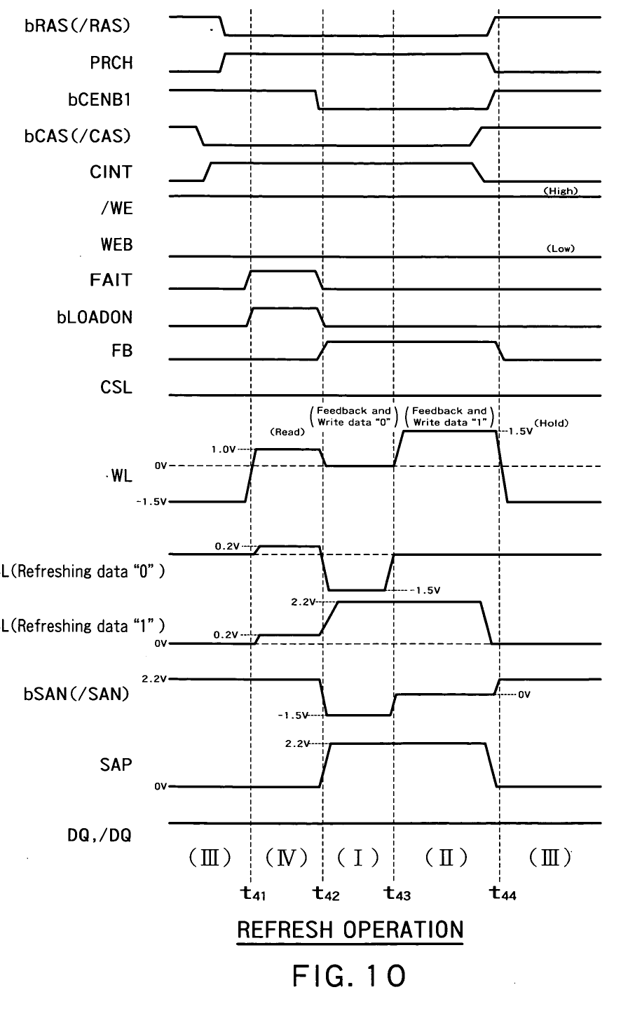

FIG. 10 is a timing chart of a refresh operation performed by the semiconductor memory device 100 according to the first embodiment. In the refresh operation shown in FIG. 10, the column select line CSL is not driven, the data is simply read from the memory cell MC, and the same data is restored to the memory cell MC. The refresh operation is identical to the data read operation shown in FIG. 6 in other respects.

According to the first embodiment, the row decoder RD includes not only the third power supply V3 used to read the data and the first power supply V1 used to write the data “1”, but also the second power supply V2 used to write the data “0”. According to the conventional technique, the first power supply V1 used to write the data k“1” is also used to write the data “0”. The current consumed when the data “0” is written is, therefore, high. According to this embodiment, since the second power supply V2 can be arbitrarily set, the cell current consumed when the data “0” is written can be reduced.

To maintain a data write rate, the second power supply V2 may be set low within an allowable range while being set lower than the first power supply V1. By so setting, it is possible to suppress deterioration of the data stored in the memory cell MC and reduce the current consumption when the data “0” is written.

Preferably, the potential of the second power supply V2 is higher than the threshold of the memory cell MC so as to write the data “0” to the memory cell MC.

### Second Embodiment

A row decoder RD according to a second embodiment of the present invention differs in configuration from the row decoder according to the first embodiment. Since the second embodiment is identical to the first embodiment in the other configurations, they will not be explained herein.

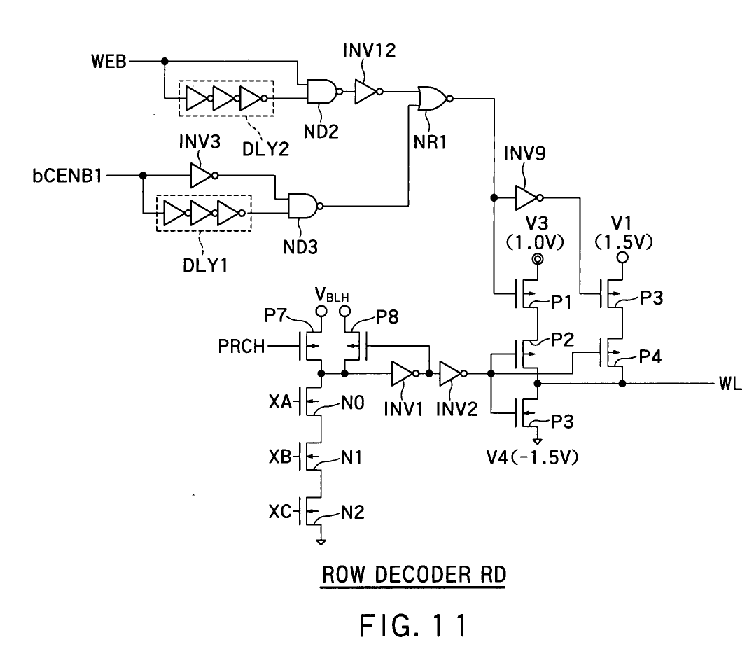

FIG. 11 is a circuit diagram of a configuration of the row decoder RD according to the second embodiment of the present invention. This row decoder RD is configured to connect one of the first power supply V1, the third power supply V3, and the fourth power supply V4 to the word line WL based on the precharge signal PRCH, the column enable signal bCENB1, and the write enable signal WEB. The row decoder RD shown in FIG. 11 does not include the second power supply V2. If the data “0” is written to the memory cell MC, the third power supply V3 is connected to the word line WL.

The signal WEB is input to one input of the NAND gate ND2, and to the other input thereof through the delay circuit DLY2. The signal bCENB1 is input to one input of the NAND gate ND3 through the inverter INV3, and to the other input through the delay circuit DLY1.

The output of the NAND gate ND2 is input to one input of the NOR gate NR1 through the inverter INV12, and the output of the NAND gate ND3 is input to the other input thereof.

The output of the NOR gate NR1 is connected to the gate of the transistor P1, and also to the gate of the transistor P3 through the inverter INV9.

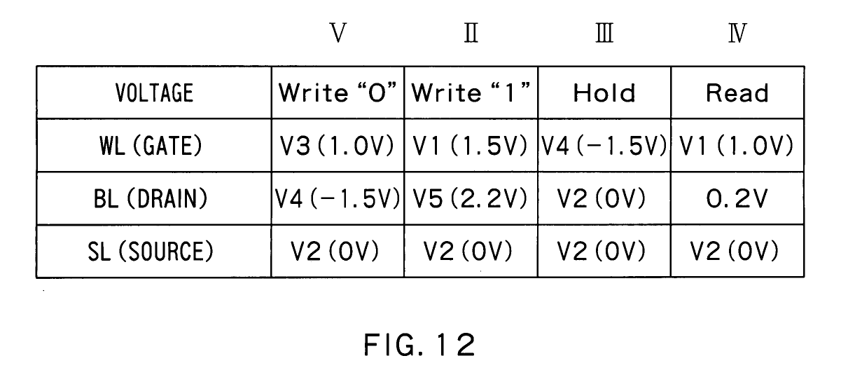

FIG. 12 is a table of potentials applied to the memory cell MC when the data is written to, held in, and read from the memory cell MC, respectively. Comparison of FIG. 12 with FIG. 5 shows that FIG. 12 differs from FIG. 5 in that the potential of the third power supply V3 (1.0 volt) is used as the potential of the word line WL in the state in which the data “0” is written to the memory cell MC (a state V). The other potentials shown in FIG. 12 are equal to those shown in FIG. 5.

[Read Operation]

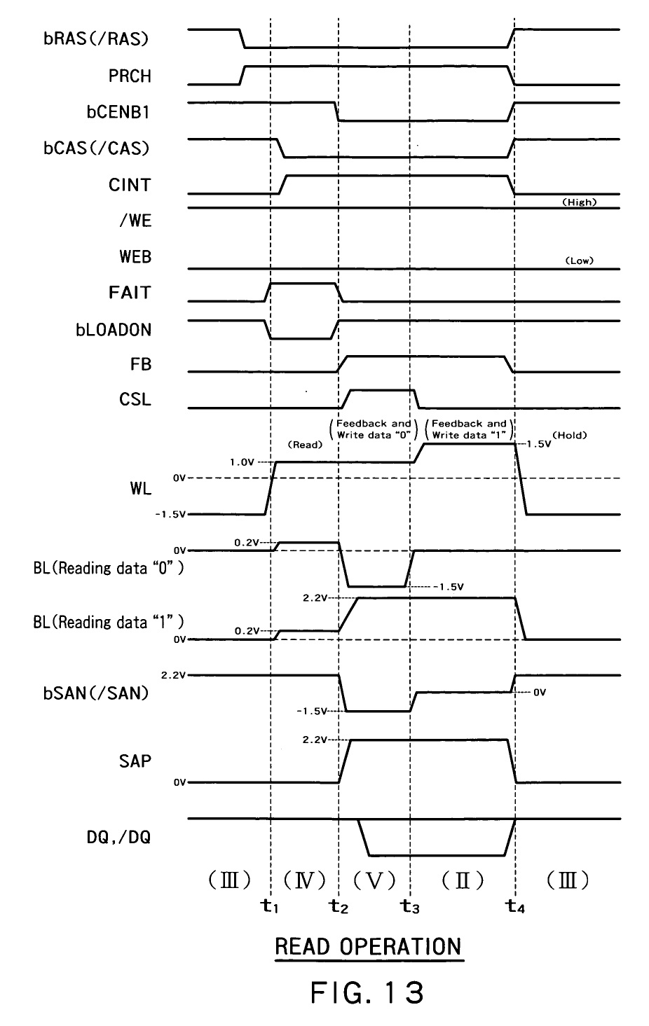

FIG. 13 is a timing chart of a data read operation performed by a semiconductor memory device 200 according to the second embodiment. The data read operation according to the second embodiment differs from that according to the first embodiment in that the potential of the word line WL when the data “0” is restored to the memory cell MC (at t2 to t3) is equal to the third potential V3 (1.0 volt) during data read (at t1 to t2). The data read operation according to the second embodiment is identical to that according to the first embodiment in the other respects.

[Write Operation and Refresh Operation]

A write operation and a refresh operation according to the second embodiment are similar to the read operation according to the first embodiment. The write operation and the refresh operation according to the second embodiment differ from those according to the first embodiment in that the potential of the word line WL when the data “0” is restored to the memory cell MC (t12 to t13 shown in FIG. 7, t22 to t23 and t24 to t25 shown in FIG. 8, and t32 to t33 and t34 to t35 shown in FIG. 9) is equal to the third potential V3 (1.0 volt) during the data read. The second embodiment is identical to the first embodiment in the other respects. Therefore, they will not be explained herein.

By making the potential of the word line WL when the data “0” is written to the memory cell MC and the potential of the word line WL when the data is read common, the row decoder RD can dispense with the second power supply V2. As a result, an increase in a circuit area of the semiconductor memory device 200 can be suppressed.

Furthermore, the potential of the third power supply V3 is lower than that of the first power supply V1 used to write the data “1” and higher than the threshold of the memory cell MC. The second embodiment, therefore, exhibits the same advantages as those of the first embodiment.

### Third Embodiment

A semiconductor memory device according to a third embodiment of the present invention uses the second power supply V2 (0 volt) only in a refresh operation. In the refresh operation, the semiconductor memory device refreshes only memory cells MC each storing the data “0”.

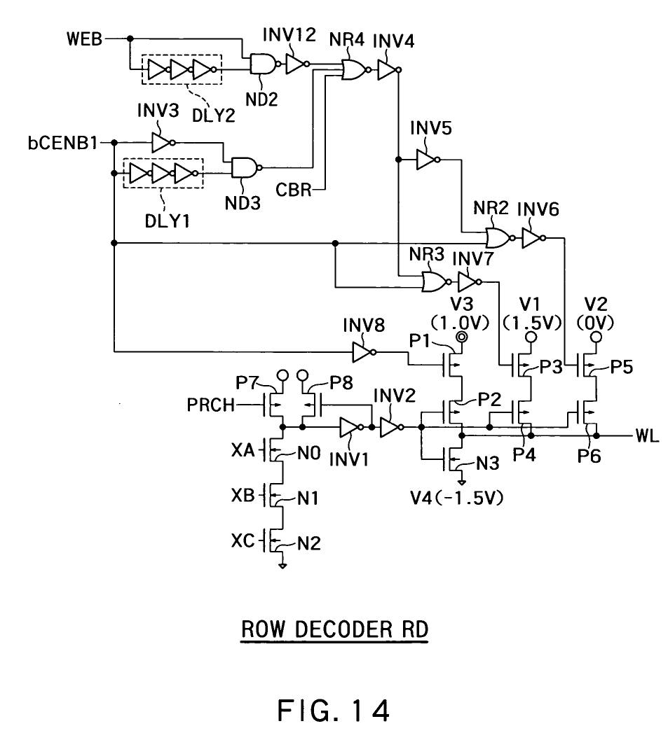

FIG. 14 is a circuit diagram of a configuration of a row decoder RD according to the third embodiment of the present invention. The row decoder RD shown in FIG. 14 differs from that shown in FIG. 3 in that the row decoder RD includes a three-input NOR gate NR4 instead of the NOR gate NR1. The output of the NAND gate ND2 is input to a first input of the NOR gate NR4 through the inverter INV12, the output of the NAND gate ND3 is input to a second input thereof, and a signal CBR (CAS Before RAS) is input to a third input thereof. The signal CBR is a refresh signal that indicates execution of the refresh operation. The signal CBR is activated when the refresh operation is executed and not activated in an ordinary data read operation and an ordinary data write operation.

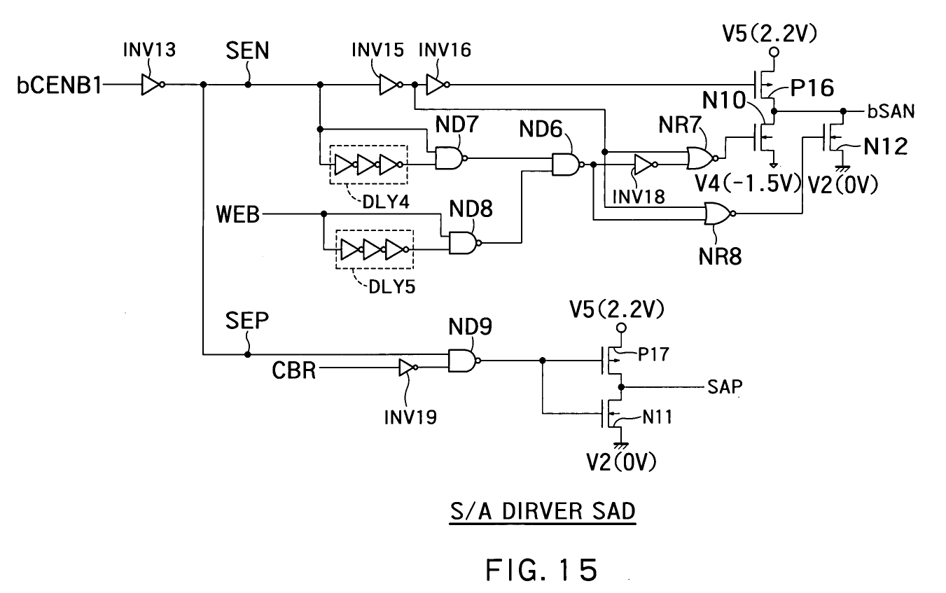

FIG. 15 is a circuit diagram of a configuration of a S/A driver SAD according to the third embodiment of the present invention. The S/A driver SAD shown in FIG. 15 differs from that shown in FIG. 4 in that the S/A driver SAD further includes a NAND gate ND9. The signal SEP is input to one input of the NAND gate ND9, and the signal CBR is input to the other input thereof through an inverter INV19. The third embodiment may be identical in configuration to that according to the first embodiment in the other respects.

The semiconductor memory device according to the third embodiment thus configured can operate similarly to the conventional semiconductor memory device in the data read operation and the data write operation, and can operate using the second power supply V2 (0 volt) in the refresh operation. In the refresh operation, the data is read from each memory cell MC and only the data “0” is written back to the memory cell MC. To write back the data “0”, the second power supply V2 (0 volt) is used.

Normally, if the memory cell MC is an n-FBC memory cell, a body potential of the memory cell MC is set lower (deeper) than a source potential and a drain potential thereof in a data holding state. Due to this, so-called “0 disturbance phenomenon” that the data “0” is changed to the data “1” occurs. Generally, in the refresh operation, it suffices to refresh only the memory cells MC each storing the data “0” so as to suppress this “0” disturbance.

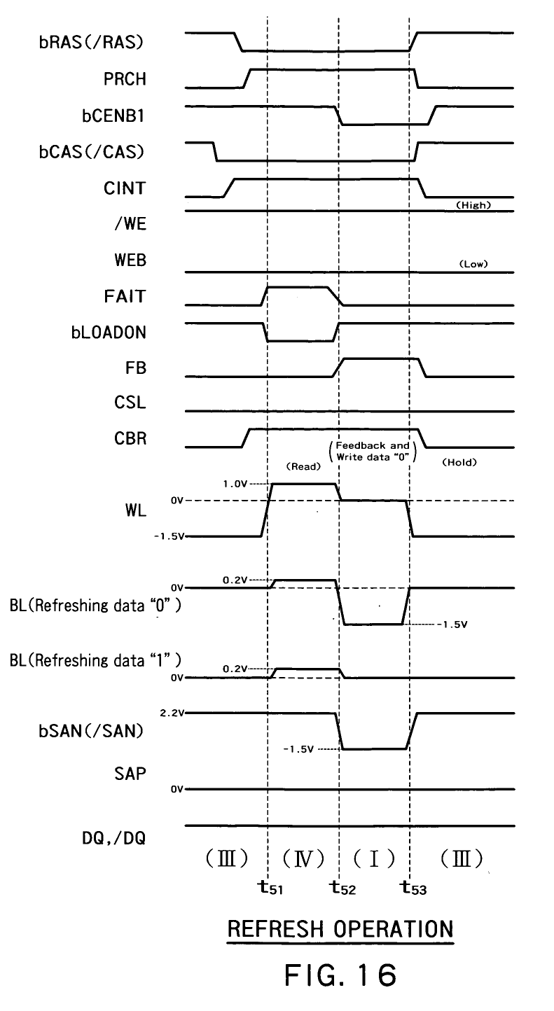

FIG. 16 is a timing chart of the refresh operation performed by the semiconductor memory device according to the third embodiment. Operations at t51 to t52 are identical to those at t41 to t42 shown in FIG. 10.

At t52 to t53, the signal SAP is not activated but remains LOW. Accordingly, after the data “1” is read from the memory cell MC, the potential of the bit line for selecting the data “1” is equal to the source potential (0 volt) according to the signal SAP. Namely, the sense amplifier S/A does not latch the data “1”.

On the other hand, the signal bSAN is supplied as the fourth power supply V4 (−1.5 volts). The sense amplifier S/A, therefore, latches the data “0” read from the memory cell MC. The data “o” can be thereby restored to the memory cell MC. Operations after t53 are identical to those after t44 shown in FIG. 10.

As can be seen, the semiconductor memory device according to the third embodiment refreshes only the memory cells MC each storing the data “0” using the second power supply V2 (0 volt). According to the third embodiment, since the memory cell MC that stores the data “1” is not refreshed in the refresh operation, the current consumption can be reduced. According to the third embodiment, when the memory cell MC that stores the data “0” is refreshed, the second power supply V2 (0 volt) lower than the fifth power supply V5 (2.2 volts) is applied to the bit line. Accordingly, the semiconductor memory device according to the third embodiment can further reduce the current consumption.

At t52 to t53, when the data “0” is written back to the memory cell MC, the row decoder RD shown in FIG. 14 connects the second power supply V2 lower than the fifth power supply V5 and higher than the threshold of the memory cell MC to the word line WD. The data “0” is thereby restored to the memory cell MC. The operation of the word line WL when the data “0” is restored is identical to that according to the first embodiment.

The semiconductor memory device according to the third embodiment can thus further reduce the current consumption. In addition, according to the third embodiment, the semiconductor memory device operates similarly to the conventional semiconductor memory device in the data read operation and the data write operation. The data “0” and the data “1” can be, therefore, executed simultaneously using the first power supply V1. As a result, the third embodiment can ensure short data write time similarly to the conventional technique.

### Fourth Embodiment

A fourth embodiment of the present invention is a combination of the second and the third embodiments. Namely, a row decoder RD according to the fourth embodiment is similar to that according to the second embodiment in that the row decoder RD does not include the second power supply V2. In addition, a semiconductor memory device according to the fourth embodiment uses the third power supply V3 (1.0 volt) only in a refresh operation. In the refresh operation, the semiconductor memory device refreshes only the memory cells MC each storing the data “0”. The configuration of fourth embodiment may be identical to that of the second or the third embodiments in the other respects.

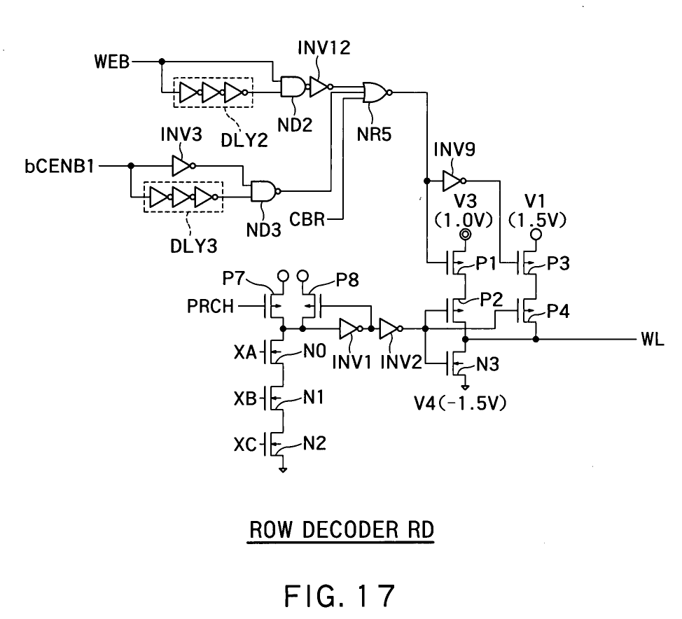

FIG. 17 is a circuit diagram of a configuration of the row decoder RD according to the fourth embodiment of the present invention. This row decoder RD is configured so that one of the first power supply VI, the third power supply V3, and the fourth power supply V4 is connected to the word line WL based on the precharge signal PRCH, the column enable signal bCENB1, the write enable signal WEB, and the signal CBR. The row decoder RD shown in FIG. 17 does not include the second power supply V2. If the data “0” is written to the memory cell MC in the refresh operation, the third power supply V3 is connected to the word line WL.

The row decoder RD includes a three-input NOR gate NR5. The output of the NAND gate ND2 is input to a first input of the NOR gate NR5 through the inverter INV12, the output of the NAND gate ND3 is input to a second input thereof, and the signal CBR is input to a third input thereof.

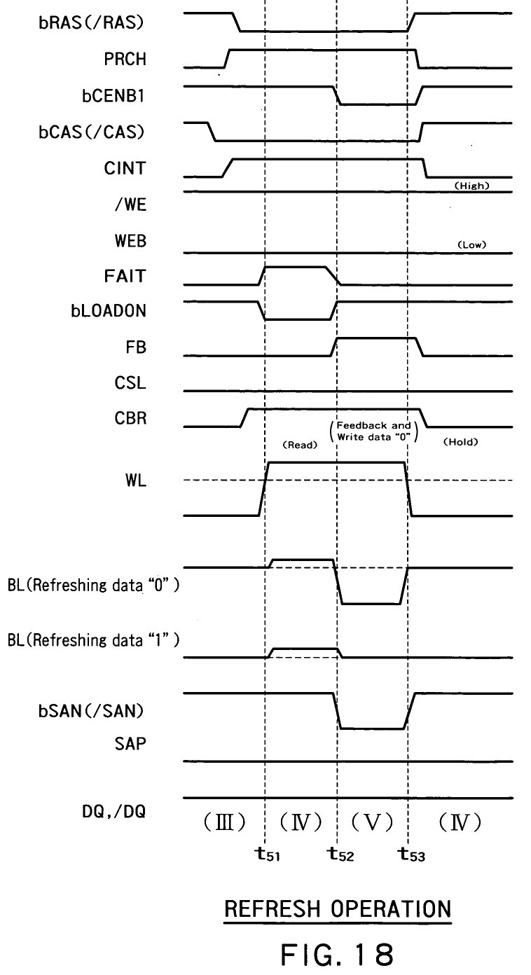

FIG. 18 is a timing chart of the refresh operation performed by the semiconductor memory according to the fourth embodiment. The refresh operation shown in FIG. 18 differs from that shown in FIG. 16 in that the potential of the word line WL when the data “0” is written back (at t52 to t53) is the third potential (1.0 volt). The refresh operation according to the fourth embodiment may be identical to the operation according to the third embodiments in the other respects.

According to the fourth embodiment, the potential of the word line WL when the data “0” is written to the memory cell MC and the potential of the word line WL when the data is read are made common. The potential of the third power supply V3 is lower than that of the first power supply V1 used to write the data “1” and higher than the threshold of the memory cell MC. The fourth embodiment, therefore, exhibits the same advantages as those of the second embodiment.

According to the fourth embodiment, in the refresh operation, the memory cell MC that stores the data “1” is not refreshed. In addition, when the memory cell MC that stores the data “0” is refreshed, the third power supply V3 (1.0 volt) lower than the fifth power supply V5 (2.2 volts) is applied to the bit line. The fourth embodiment can, therefore, exhibit the same advantages as those of the third embodiment.

### Fifth Embodiment

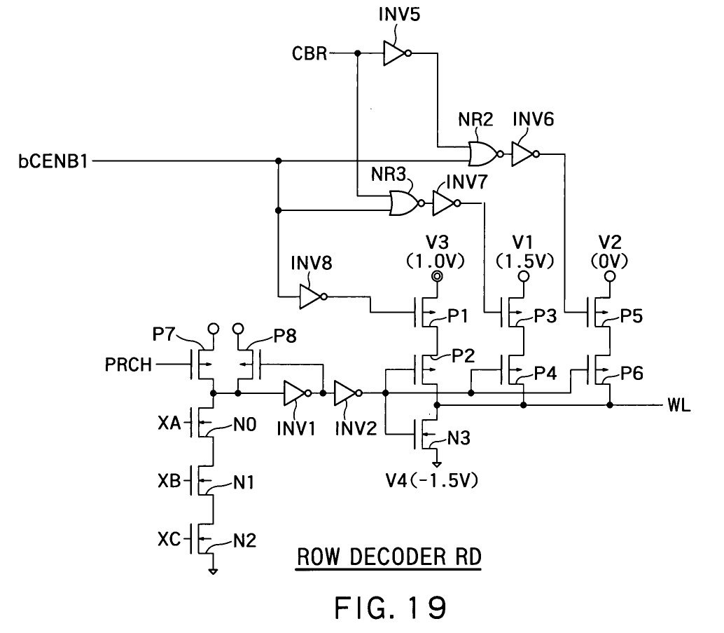

FIG. 19 is a circuit diagram of a row decoder RD of a semiconductor memory device according to a fifth embodiment of the present invention. The configuration of the semiconductor memory device according to the fifth embodiment may be identical to the semiconductor memory device according to any one of the first to the fourth embodiments in the other respects. The row decoder RD according to the fifth embodiment is made simpler than the row decoder RD according to the third embodiment. More specifically, the row decoder RD according to the fifth embodiment does not receive the signal WEB. In addition, the row decoder RD does not include the delay circuits DLY1 and DLY2.

The signal CBR is input to one input of the NOR gate NR2 through the inverter INV5, and the signal bCENB1 is input to the other input thereof. The output of the NOR gate NR2 is connected to the gate of the transistor P5 through the inverter INV6. The signal CBR is input to one input of the NOR circuit NR3, and the signal bCENB1 is input to the other input thereof. The output of the NOR gate NR3 is connected to the gate of the transistor P3 through the inverter INV7. The signal bCENB1 is input to the gate of the transistor P1 through the inverter INV8. Other configurations of the row decoder RD shown in FIG. 19 may be identical to those of the row decoder RD shown in FIG. 14.

The semiconductor memory device according to the fifth embodiment operates similarly to that according to the third embodiment. More specifically, in a data read operation and a data write operation, the signal CBR is inactive (LOW) and the second power supply V2 is not, therefore, used. Accordingly, the semiconductor memory device according to the fifth embodiment operates similarly to the conventional semiconductor memory device in the data read operation and the data write operation.

In a refresh operation, since the signal CBR is activated into HIGH, the semiconductor memory device according to the fifth embodiment can use the second power supply V2 (0 volt). The second power supply V2 (0 volt) is connected to the word line WL when the data “0” is restored to the memory cell MC. In this refresh operation, the semiconductor memory device refreshes only the memory cells MC each storing the data “0”. In addition, the semiconductor memory device according to the fifth embodiment operates similarly to the conventional semiconductor memory device in the data read operation and the data write operation.

The fifth embodiment exhibits the same advantages as those of the third embodiment. Furthermore, since the row decoder RD is relatively simple, it is possible to reduce a circuit area of the semiconductor memory device.

### Sixth Embodiment

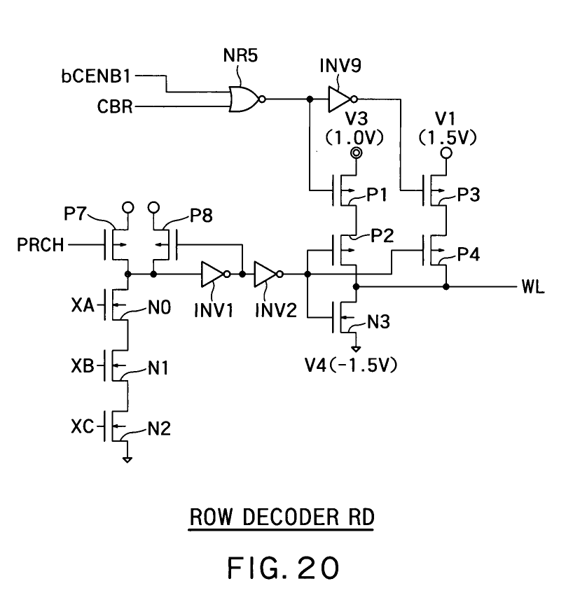

FIG. 20 is a circuit diagram of a configuration of a row decoder RD of a semiconductor memory device according to a sixth embodiment of the present invention. The semiconductor memory device according to the sixth embodiment may be identical to the semiconductor memory device according to any one of the first to the fourth embodiments. The row decoder RD according to the sixth embodiment is made simpler than the row decoder RD according to the fourth embodiment. More specifically, the row decoder RD according to the sixth embodiment does not receive the signal WEB. In addition, the row decoder RD does not include the delay circuits DLY1 and DLY2.

The signal bCENB1 is input to one input of the NOR gate NR5, and the signal CBR is input to the other input thereof. The output of the NOR gate NR5 is connected to the gate of the transistor P1, and to the gate of the transistor P3 through the inverter INV9.

Other configurations of the row decoder RD shown in FIG. 20 may be identical to those of the row decoder RD shown in FIG. 11.

The semiconductor memory device according to the sixth embodiment operates similarly to that according to the fourth embodiment. More specifically, the potential of the word line WL when the data “0” is written and the potential (third potential (1.0 volt)) of the word line when the data is read are made common.

In a data read operation and a data write operation, the signal CBR is inactive (LOW) and the first power supply V1 or the third power supply V3 is connected to the word line WL by the operation of the signal bCENB1. Accordingly, the semiconductor memory device according to the sixth embodiment operates similarly to the semiconductor memory device according to the fourth embodiment in the data read operation and the data write operation.

In a refresh operation, since the signal CBR is activated into HIGH, the semiconductor memory device according to the sixth embodiment uses only the third power supply V3 and does not use the first power supply V1. Therefore, the semiconductor memory device according to the sixth embodiment also operates similarly to the semiconductor memory device according to the fourth embodiment in the refresh operation.

The sixth embodiment exhibits the same advantages as those of the fourth embodiment. Furthermore, since the configuration of the row decoder RD is relatively simple, it is possible to reduce a circuit area of the semiconductor memory device.

1. A semiconductor memory device comprising:
a memory cell including a floating body region in an electrically floating state and storing data by accumulating or discharging charges in or from the floating body region;
a memory cell array including a plurality of the memory cells;
a word line connected to a gate of the memory cell;
a bit line connected to a diffusion layer of the memory cell;
a sense amplifier connected to the bit line; and
a decoder applying a first potential to the word line when data “1” is written to the memory cell and applying a second potential different from the first potential to the word line when data “0” is written to the memory cell.

2. The semiconductor memory device according to claim 1, wherein
the decoder applies a third potential different from the first potential and the second potential to the word line when data stored in the memory cell is read.

3. The semiconductor memory device according to claim 1, wherein
the second potential is closer to a source potential of the memory cell than the first potential and is higher than a threshold voltage of the memory cell storing data “0”.

4. The semiconductor memory device according to claim 1, wherein
the second potential is equal to a source potential of the memory cell and is higher than a threshold voltage of the memory cell storing data “0”.

5. The semiconductor memory device according to claim 1, wherein
the second potential is equal to a potential applied to the word line when data is read out from the memory cell.

6. The semiconductor memory device according to claim 1, wherein
the decoder applies a third potential different from the first potential and the second potential to the word line when the data stored in the memory cell is read, and
the semiconductor memory device further comprises a sense amplifier driver which drives the sense amplifier to apply a fourth potential different from the first to the third potentials to the bit line when the data “0” is written to the memory cell and to apply a source potential to the bit line connected to the memory cell to which the data “0” is already written and further to apply a fifth potential different from the first to the fourth potentials to the bit line connected to the memory cell to which the data “1” is written when the data “1” is written to the memory cell.

7. The semiconductor memory device according to claim 6, wherein
the fourth potential is a potential different in polarity from the first potential, the second potential, the third potential, and the fifth potential, and
the fifth potential is further away from the source potential than any one of the first to the third potentials.

8. The semiconductor memory device according to claim 7, wherein
the first to the fifth potentials are higher in an order of the fourth potential, the second potential, the first potential, and the fifth potential.

9. The semiconductor memory device according to claim 1, wherein
the decoder includes a first delay circuit which determines an end of a data “0” write-back operation in a data read operation based on a column enable signal for enabling activation of the word line.

10. The semiconductor memory device according to claim 1, wherein
the decoder includes a second delay circuit which determines an end of a data “0” writing operation based on a write enable signal for enabling activation of a writing operation of the semiconductor memory device.

11. The semiconductor memory device according to claim 6, wherein
the sense amplifier driver includes a third delay circuit which determines an end of a data “0” write-back operation in a data read operation based on a column enable signal for enabling activation of the word line.

12. The semiconductor memory device according to claim 6, wherein
the sense amplifier driver includes a fourth delay circuit which determines an end of a data “0” writing operation based on a write enable signal for enabling activation of a writing operation of the semiconductor memory device.

13. The semiconductor memory device according to claim 1, wherein
the decoder receives a refresh signal indicating an execution of a refresh operation,
when the refresh operation is inactive, the decoder applies the first potential to the word line when the data “1” and the data “0” is written to the memory cell, and
when the refresh operation is active, the decoder applies the first potential to the word line when the data “1” is written to the memory cell, and applies the second potential different from the first potential to the word line when the data “0” is written to the memory cell.

14. The semiconductor memory device according to claim 13, wherein
the second potential is closer to a source potential of the memory cell than the first potential and is higher than a threshold voltage of the memory cell storing data “0”.

15. The semiconductor memory device according to claim 13, wherein
the second potential is equal to a source potential of the memory cell and is higher than a threshold voltage of the memory cell storing data “0”.

16. The semiconductor memory device according to claim 13, wherein
the second potential is equal to a potential applied to the word line when data is read out from the memory cell.

17. The semiconductor memory device according to claim 1, wherein
the decoder applies a third potential different from the first potential and the second potential to the word line when the data stored in the memory cell is read,
the semiconductor memory device further comprising: a sense amplifier driver receiving a refresh signal indicating an execution of a refresh operation, wherein
when the refresh operation is inactive, the sense amplifier driver applies a fourth potential different from the first to the third potentials to the bit line when the data “0” is written to the memory cell, and applies a source potential to the bit line connected to the memory cell to which the data “0” is already written when the data “1” is written, and further applies a fifth potential different from the first to the fourth potentials to the bit line connected to the memory cell to which the data “1” is written,
when the refresh operation is active, the sense amplifier driver applies the fourth potential to the bit line when the data “1” is not written but the data “O” is written to the memory cell, and applies a fifth potential different from the first to the fourth potentials to the bit line connected to the memory cell to which the data “1” is written.

18. The semiconductor memory device according to claim 17, wherein
the second potential is equal to a source potential of the memory cell and is higher than a threshold voltage of the memory cell storing data “0”.

19. A method for driving a semiconductor memory device, the semiconductor memory device comprising a memory cell including a floating body region in an electrically floating state and storing data by accumulating or discharging charges in or from the floating body region; a memory cell array including a plurality of the memory cells; a word line connected to a gate of the memory cell; a bit line connected to a diffusion layer of the memory cell; a sense amplifier connected to the bit line; and a decoder applying potentials to the word line,
the method comprising:
applying a first potential to the word line when data “1” is written to the memory cell; and
applying a second potential different from the first potential to the word line when data “0” is written to the memory cell.
